(19) United States
(12) Patent Application Publication
(10) Pub. No.: US 2025/0123243 A1
(43) Pub. Date: Apr. 17, 2025

(54) SEMICONDUCTOR SUBSTRATE INSPECTION DEVICE

(71) Applicant: SAMSUNG ELECTRONICS CO., LTD., Suwon-si (KR)

(72) Inventors: Hyeon Bo SHIM, Suwon-si (KR); Souk KIM, Suwon-si (KR); Younghoon SOHN, Suwon-si (KR); Jaeho KIM, Suwon-si (KR); Inseok PARK, Suwon-si (KR); Jaewon YANG, Suwon-si (KR); Minho RIM, Suwon-si (KR)

(73) Assignee: SAMSUNG ELECTRONICS CO., LTD., Suwon-si (KR)

(21) Appl. No.: 18/670,118

(22) Filed: May 21, 2024

(30) Foreign Application Priority Data
Oct. 17, 2023 (KR) 10-2023-0138998

(51) Int. Cl. G01N 29/04; G01N 29/24

(52) U.S. Cl. CPC G01N 29/041; G01N 29/2418; G01N 29/2431; G01N 2291/0289; G01N 2291/2697

(57) ABSTRACT

A semiconductor substrate inspection device is provided and includes: a function generator that generates a first signal and a second signal; an ultrasonic generator that receives the first signal generated from the function generator, generates an ultrasonic wave based on the first signal, and generates a surface wave signal on an upper surface of a substrate using the ultrasonic wave; and an electron beam measurer that inspects the surface wave signal, wherein the electron beam measurer includes: a laser light source that receives the second signal generated from the function generator and generates a first pulse laser beam based on the second signal; an electron beam generator that receives the first pulse laser beam and generates an electron beam that is emitted onto the upper surface of the substrate; and a backscattered electron detector that detects backscattered electrons generated based on the electron beam being incident on the substrate.

### CROSS-REFERENCE TO RELATED APPLICATION

This application is based on and claims priority under 35 U.S.C. § 119 to Korean Patent Application No. 10-2023-0138998, filed on Oct. 17, 2023, in the Korean Intellectual Property Office, the disclosure of which is incorporated by reference herein in its entirety.

### BACKGROUND

### 1. Technical Field

Embodiments of the present disclosure relate to a semiconductor substrate inspection device.

### 2. Brief Description of Related Art

As electronic products become compact and multi-functional and require high performance, high-capacity semiconductor memory devices are required. Since the degree of integration of two-dimensional semiconductor memory devices according to the related art is mainly affected by reduction in areas occupied by unit memory cells, semiconductor devices are becoming more highly integrated.

Accordingly, a method of monitoring each of semiconductor manufacturing processes is required, and thus, non-destructive inspection having a high inspection speed has become essential. Recently, in order to achieve the above requirements, research has been conducted on photoacoustic inspection and backscattered electron signal inspection of electron beams.

### SUMMARY

Embodiments of the present disclosure provide a semiconductor substrate inspection device exhibiting improved reliability.

According to embodiments of the present disclosure, a semiconductor substrate inspection device is provided and includes: a function generator configured to generate a first signal and a second signal; an ultrasonic generator configured to receive the first signal generated from the function generator, generate an ultrasonic wave based on the first signal, and generate a surface wave signal on an upper surface of a substrate using the ultrasonic wave; and an electron beam measurer configured to inspect the surface wave signal, wherein the electron beam measurer includes: a laser light source configured to receive the second signal generated from the function generator and generate a first pulse laser beam based on the second signal; an electron beam generator configured to receive the first pulse laser beam and generate an electron beam that is emitted onto the upper surface of the substrate; and a backscattered electron detector configured to detect backscattered electrons generated based on the electron beam being incident on the substrate.

According to embodiments of the present disclosure, a semiconductor substrate inspection device is provided and includes: an ultrasonic generator configured to generate an ultrasonic wave that is modulated, wherein the ultrasonic wave generates a surface wave signal on an upper surface of a substrate; an electron beam generator configured to scan the upper surface of the substrate and generate an electron beam that is scattered by interference with the surface wave signal; a backscattered electron detector configured to detect backscattered electrons that are generated based on the electron beam being incident on the substrate; a secondary electron detector configured to detect secondary electrons generated from the substrate; a laser light source configured to generate a first pulse laser beam, wherein a period of the electron beam, generated by the electron beam generator, is based on a pulse frequency of the first pulse laser beam; a beam splitter configured to extract a second pulse laser beam from the first pulse laser beam; a mirror on a path of the second pulse laser beam, the mirror configured to cause the second pulse laser beam to be incident on the upper surface of the substrate; and a function generator configured to generate a first function signal and a second function signal, and transmit the first function signal and the second function signal to the ultrasonic generator and the laser light source, respectively.

According to embodiments of the present disclosure, a semiconductor substrate inspection device is provided and includes: an ultrasonic generator configured to generate a first ultrasonic wave that is modulated, wherein the first ultrasonic wave generates a surface wave signal on an upper surface of a substrate; an electron beam generator configured to scan the upper surface of the substrate and generate an electron beam that is scattered by interference with the surface wave signal; a backscattered electron detector configured to detect backscattered electrons that are generated based on the electron beam being incident on the substrate; a secondary electron detector configured to detect secondary electrons generated from the substrate; an energy filter on one side of the backscattered electron detector and configured to filter the secondary electrons to cancel or reduce signal noise caused by the backscattered electrons; a laser light source configured to generate a first pulse laser beam, wherein a period of the electron beam, generated by the electron beam generator, is based on a pulse frequency of the first pulse laser beam; a beam splitter configured to extract a second pulse laser beam from the first pulse laser beam; a mirror on a path of the second pulse laser beam, the mirror configured to cause the second pulse laser beam to be incident on the upper surface of the substrate; and a function generator configured to generate a first function signal and a second function signal, and transmit the first function signal and the second function signal to the ultrasonic generator and the laser light source, respectively, wherein the second pulse laser beam is emitted onto the upper surface of the substrate and generates a second ultrasonic wave by a photoacoustic effect, wherein the second pulse laser beam is incident on the substrate along an axis different from an axis along which the electron beam is incident on the substrate, wherein the beam splitter includes a color filter that is configured to adjust a wavelength of the first pulse laser beam or the second pulse laser beam, wherein the first pulse laser beam and the second pulse laser beam have wavelengths different from each other, wherein the first pulse laser beam and the second pulse laser beam have a same pulse frequency, wherein the ultrasonic generator is on a lower surface of the substrate, wherein the first ultrasonic wave generated from the ultrasonic generator has a frequency of 10 kHz to 10 MHz and is transmitted from a lower portion of the substrate to an upper portion of the substrate, wherein the second ultrasonic wave generated by the second pulse laser beam is transmitted to the lower portion of the substrate, reflected from the lower portion of the substrate, and transmitted to the upper portion of the substrate, wherein the second ultrasonic wave generated by the second pulse laser beam interferes with the first ultrasonic wave generated by the ultrasonic generator and is thus amplified or cancelled, and wherein the surface wave signal generated by the ultrasonic generator interferes with the electron beam and is sensed by the backscattered electron detector and the secondary electron detector.

### BRIEF DESCRIPTION OF DRAWINGS

Embodiments will be more clearly understood from the following detailed description taken in conjunction with the accompanying drawings in which:

FIG. 1 is a block diagram of a semiconductor substrate inspection device according to an embodiment;

FIG. 2A is a conceptual diagram illustrating a semiconductor substrate inspection device according to an embodiment;

FIG. 2B is a conceptual diagram showing a semiconductor substrate inspection device according to another embodiment;

FIG. 3 is a conceptual diagram showing a state in which a substrate inspection is performed using an ultrasonic generation module on a defect-free substrate, according to an embodiment;

FIG. 4 is a conceptual diagram showing a state in which a substrate inspection is performed using the ultrasonic generation module on a defective substrate, according to an embodiment;

FIG. 5 is a conceptual diagram showing a state in which a substrate inspection is performed using a pulse laser beam on a defect-free substrate, according to an embodiment;

FIG. 6 is a conceptual diagram showing a state in which a substrate inspection is performed using the pulse laser beam on a defective substrate, according to an embodiment;

FIG. 7 is a cross-sectional view showing a substrate according to an embodiment;

FIGS. 8A to 8C are images derived by inspection of a substrate, according to an embodiment;

FIG. 9 is a cross-sectional view showing a substrate according to an embodiment;

FIGS. 10A to 10D are images derived by inspection of a substrate, according to an embodiment; and

FIG. 11 is a flowchart of a semiconductor substrate inspection according to an embodiment.

### DETAILED DESCRIPTION

Embodiments of the present disclosure may have diverse changes and various forms, and thus, some example embodiments are illustrated in the drawings and described in detail. However, this is not intended to limit the embodiments of the present disclosure to some specific embodiments. Also, the embodiments described below are only examples, and thus, various changes may be made to the example embodiments.

All examples and illustrative terms are only used to explain aspects of the present disclosure in detail and, thus, the scope of the present disclosure is not limited by these examples and illustrative terms.

Unless otherwise specified, the horizontal direction parallel to the ground is defined as a first direction X and a second direction Y perpendicular to the first direction X. Also, the direction perpendicular to the ground, that is, the direction perpendicular to both the first direction X and the second direction Y, is defined as a vertical direction Z.

It will be understood that when an element is referred to as being “on,” “connected to,” or “coupled to” another element, it can be directly on, connected to, or coupled to the other element or intervening elements may be present. In contrast, when an element is referred to as being “directly on,” “directly connected to,” or “directly coupled to” another element, there are no intervening elements present.

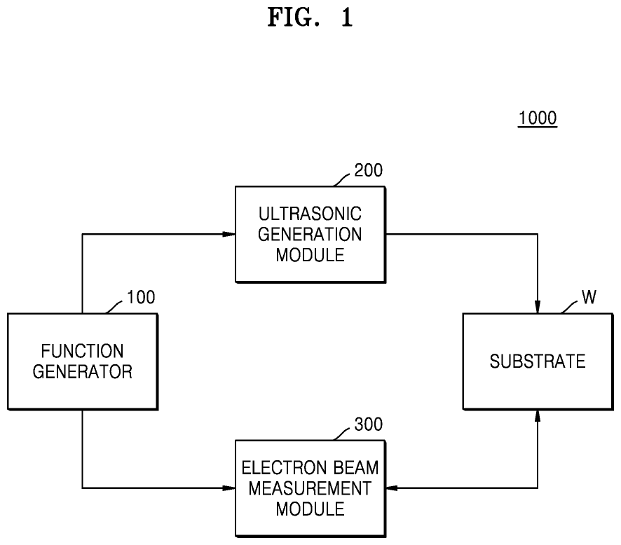

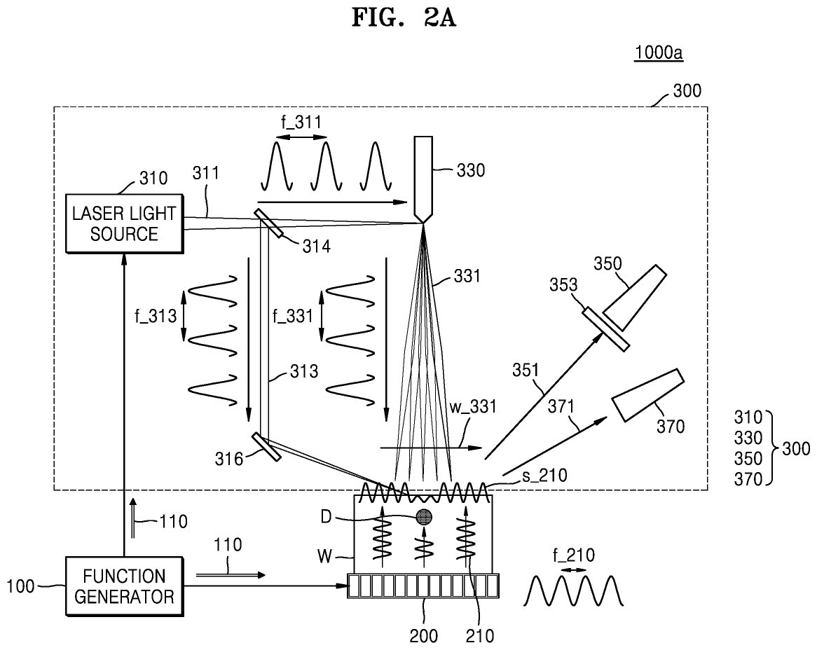

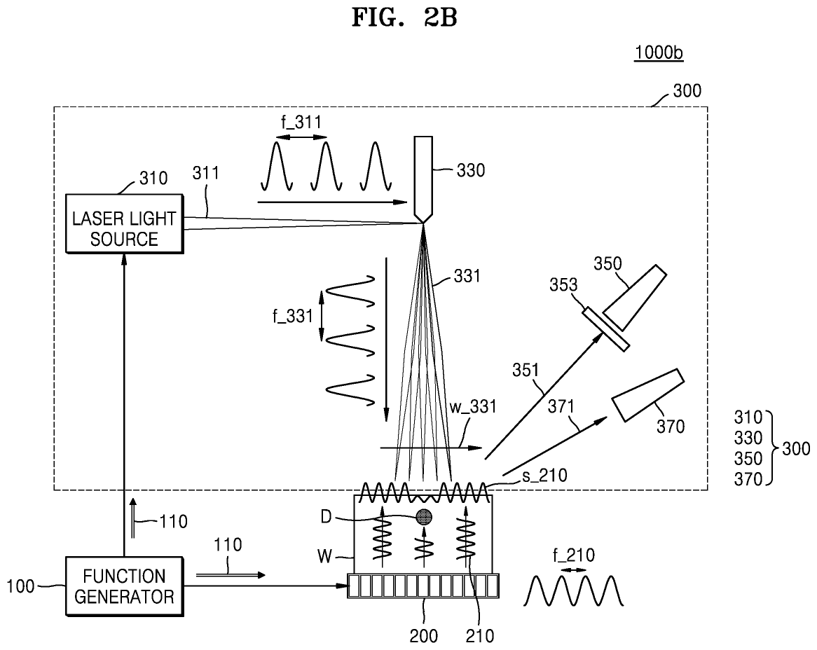

FIG. 1 is a block diagram of a semiconductor substrate inspection device 1000 according to an embodiment. FIG. 2A is a conceptual diagram illustrating a semiconductor substrate inspection device 1000a according to an embodiment. FIG. 2B is a conceptual diagram showing a semiconductor substrate inspection device 1000b according to another embodiment.

Referring to FIGS. 1 to 2B, each of the semiconductor substrate inspection device 1000, the semiconductor substrate inspection device 1000a, and the semiconductor substrate inspection device 1000b according to an embodiment of the present disclosure may include a function generator 100, an ultrasonic generation module 200 (e.g., an ultrasonic generation generator), and an electron beam measurement module 300 (e.g., an electron beam measurer). When a substrate W is placed on a stage and preparations for inspection are completed, the function generator 100 may generate function signals used for measurement. According to embodiments, the stage may support the substrate W that is subject to inspection. For example, the stage may include a wafer chuck. For example, the stage may include a three-point wafer chuck and/or a hole-type wafer chuck. The wafer chuck may be placed on a stage body. The stage body may be operated by a motor and may be transparent. The stage may move in a straight line in the x-direction, y-direction, or z-direction to move the substrate W in the x-direction, y-direction, or z-direction.

The ultrasonic generation module 200 may generate an ultrasonic wave 210 and transmit the ultrasonic wave 210 to the substrate W, and the electron beam measurement module 300 may emit a pulse laser beam to the substrate W using a laser light source 310 or scan the substrate W using an electron beam generator 330. The electron beam scattered after the substrate W is scanned may be incident back into an electron detector of the electron beam measurement module 300.

The substrate W may include a silicon bulk wafer, an epitaxial wafer, or the like. The epitaxial wafer may include a crystalline material layer, that is, an epitaxial layer, grown by an epitaxial process on a bulk wafer. However, the substrate W is not limited to the bulk wafer or the epitaxial wafer. For example, the substrate W may include various types of wafers, such as polished wafers, annealed wafers, and silicon on insulator (SOI) wafers. The substrate W may include a plurality of semiconductor chips. The substrate W may be separated into individual semiconductor chips by a subsequent singulation process. The semiconductor chips may include identical patterns that constitute a semiconductor device. The patterns on the substrate W or the semiconductor chip may be formed by a series of semiconductor processes, such as a photolithography process and/or an etching process.

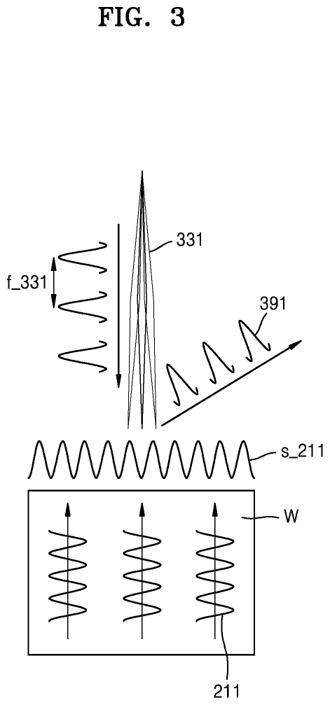

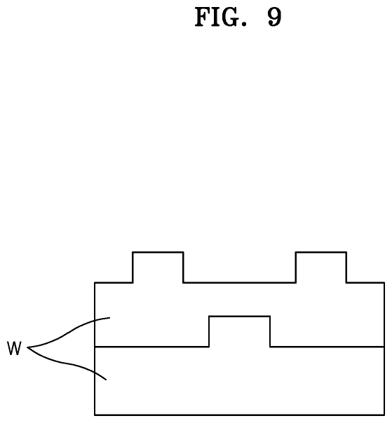

The semiconductor substrate inspection device 1000, the semiconductor substrate inspection device 1000a, and the semiconductor substrate inspection device 1000b may inspect an object to be inspected, such as the substrate W. For example, the semiconductor substrate inspection device 1000, the semiconductor substrate inspection device 1000a, and the semiconductor substrate inspection device 1000b may inspect at least one defect D formed inside the substrate W. For example, the semiconductor substrate inspection device 1000, the semiconductor substrate inspection device 1000a, and the semiconductor substrate inspection device 1000b may inspect the detailed shape of the substrate W that includes a plurality of layers, as shown in FIG. 9. For example, the semiconductor substrate inspection device 1000, the semiconductor substrate inspection device 1000a, and the semiconductor substrate inspection device 1000b may non-destructively inspect an object to be inspected, such as the substrate W. The semiconductor substrate inspection device 1000, the semiconductor substrate inspection device 1000a, and the semiconductor substrate inspection device 1000b may perform photoacoustic inspection (e.g., ultrasonic inspection) and electron beam measurement inspection. The inspection process is described below in detail with reference to FIGS. 3 to 10D.

The photoacoustic inspection includes applying an optical signal to an object to be inspected, such as the substrate W, and sensing an acoustic signal generated by the object to be inspected, such as the substrate W, in response to the optical signal. A portion of the object to be inspected, such as the substrate W, which absorbs the optical signal expands due to an increase in temperature. Here, the optical signal includes a pulse or pulse train, and the length of each pulse has to be shorter than the characteristic time of heat diffusion caused by the optical signal. This constraint is referred to as thermal confinement. A pressure wave is generated by rapid expansion of a portion of the substrate W due to absorption of the optical signal, and as a result, the acoustic signal in an ultrasonic frequency band may be generated. The ultrasonic wave may have high transmissivity and slow propagation speeds inside metallic and/or semiconductor materials. Therefore, the photoacoustic inspection may measure the thickness of metal and/or semiconductor materials with high reliability.

The function generator 100 may generate signals 110, and the signals 110 may include a function signal. Each of the signals 110 may include a very short pulse signal. The signal 110 generated in the function generator 100 may be transmitted to the ultrasonic generation module 200 or the laser light source 310 of the electron beam measurement module 300.

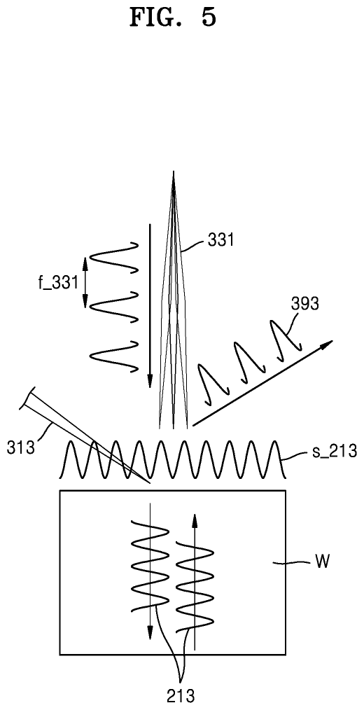

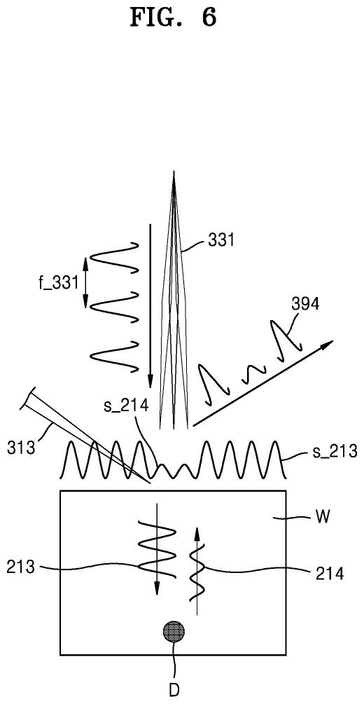

The signal 110 generated from the function generator 100 may include a lock-in signal. When the signal 110 generated from the function generator 100 includes a lock-in signal, the function generator 100 may further include a lock-in-amplifier. The lock-in signal may synchronize the first pulse laser beam 311 and the ultrasonic wave 210 with each other. When the first pulse laser beam 311 and the ultrasonic wave 210 are synchronized with each other, the semiconductor substrate inspection device 1000a may easily control the first pulse laser beam 311 and the ultrasonic wave 210. As used herein, the feature in which the waveforms of the first pulse laser beam 311 and the ultrasonic wave 210 are synchronized with each other may indicate that the (main) peaks of the two waveforms are formed at substantially the same moment. In order to synchronize the waveforms of the first pulse laser beam 311 and the ultrasonic wave 210 with each other, the function generator 100 may delay and/or adjust the first pulse laser beam 311 and/or the ultrasonic wave 210. A second pulse laser beam 313 may be extracted from the first pulse laser beam 311. Referring to FIGS. 5 and 6 together, an ultrasonic wave 213 may be generated by the second pulse laser beam 313. In this case, the ultrasonic wave 213 may be consequently synchronized with the second pulse laser beam 313. Accordingly, when the first pulse laser beam 311 and the second pulse laser beam 313 are synchronized with each other, the first pulse laser beam 311 may be synchronized with the ultrasonic wave 213. Also, the first pulse laser beam 311 may be input to the electron beam generator 330 and adjust a pulse frequency f_331 (also referred to as an electron beam-pulse frequency) of an electron beam 331. Consequently, according to embodiments of the present disclosure, the function generator 100 may be configured to synchronize the first pulse laser beam 311, the second pulse laser beam 313, the electron beam 331, and/or the ultrasonic wave 210 with each other.

The function generator 100 may be configured to individually modulate the amplitude and pulse frequency of the signal 110 input to the ultrasonic generation module 200 and the amplitude and pulse frequency of the signal 110 input to the laser light source 310. The function generator 100 may allow the source of the ultrasonic generation module 200 and the electron beam measurement module 300 including the laser light source 310 to generate a signal having a frequency, amplitude, or pulse frequency on the basis of an optimized wavelength depending on the substrate W. That is, the function generator 100 may not only generate a simple frequency lock-in but also generate and transmit a specific function signal for adjusting the waveform of the ultrasonic generation module 200 and/or the electron beam measurement module 300.

The ultrasonic generation module 200 may receive the signal 110 generated from the function generator 100 and then generate the ultrasonic wave 210. The ultrasonic generation module 200 may be disposed below the substrate W. The ultrasonic generation module 200 may modulate the waveform of the signal 110 received from the function generator 100 and transmit the modulated waveform to the lower surface of the substrate W. A general ultrasonic generation module may include a single ultrasonic transducer that converts the signal 110 into only one ultrasonic wave. On the other hand, the ultrasonic generation module 200 according to an embodiment of the present disclosure may be provided as an array structure or a plurality of transducers. Accordingly, the ultrasonic generation module 200 may adjust the waveform and/or frequency of the ultrasonic wave 210 differently, depending on the shape, internal structure, and constituent material of the substrate W to be measured. As a result, in the ultrasonic wave 210 transmitted to the upper portion of the substrate W, the contrast of defects in a structure to be measured increases, and thus, the defects may be more clearly identified.

The ultrasonic wave 210, that is modulated, generated by the ultrasonic generation module 200 in the lower portion of the substrate W may have a frequency of about 10 kHz to about 10 MHz. One or more ultrasonic waves 210, that are modulated, may be generated by the ultrasonic generation module 200. The ultrasonic waves 210 may be transmitted in an upward direction from the lower portion to the upper portion of the substrate W, the ultrasonic waves 210 interfered by an inner structure of the substrate W may be transmitted to the upper portion of the substrate W, and the ultrasonic waves 210 may generate a surface wave signal s_210 having the waveform that changes depending on the inner structure of the substrate W. The frequency of the ultrasonic wave 210 depends on the amplitude and wavelength thereof generated from the ultrasonic generation module 200 (e.g., an ultrasonic pulse frequency f_210 of the ultrasonic wave 210) may be determined based on the signal 110 generated by the function generator 100. However, even in this case, the ultrasonic generation module 200 may autonomously modulate the signal 110 depending on the thickness and/or inner structure of the substrate W, rather than simply receiving the signal 110 generated from the function generator 100 without modulation and generating a single ultrasonic wave.

The signal 110 generated from the function generator 100 may be transmitted to the electron beam measurement module 300, and more specifically, to the laser light source 310 of the electron beam measurement module 300.

The electron beam measurement module 300 may inspect the surface wave signal s_210 that contains information about an inside of the substrate W. The electron beam measurement module 300 may include a laser light source 310 that receives the signal 110 generated from the function generator 100 and generates the first pulse laser beam 311, an electron beam generator 330 that receives the first pulse laser beam 311 and generates the electron beam 331 emitted onto the upper surface of the substrate W, a backscattered electron detector 350 that detects backscattered electrons 351 generated when the electron beam 331 collides with the substrate W, a secondary electron detector 370 that detects secondary electrons 371 generated from the substrate W, and an energy filter 353 that is located on one side of the backscattered electron detector 350.

The laser light source 310 may generate and output a pulse laser beam. For example, the laser light source 310 may include a Nd:YAG laser oscillator. The laser light source 310 may generate and output, for example, a femtosecond (fs) or picosecond (ps) laser beam. Here, the laser beam may have a pulse length of about 1 fs to about 1 ps. However, the pulse length of the laser beam is not limited to this range.

Also, the laser beam may have visible and/or infrared wavelengths. For example, the laser beam may have visible and/or near infrared (NIR) wavelengths. In the semiconductor substrate inspection device 1000, the semiconductor substrate inspection device 1000a, and the semiconductor substrate inspection device 1000b according to the embodiment, the first pulse laser beam 311 generated from the laser light source 310 may include ultraviolet (UV) light having a wavelength of about 100 nm to about 400 nm. The frequency according to the wavelength of the first pulse laser beam 311 may be formed differently depending on the laser light source 310, but the amplitude and/or pulse frequency of the first pulse laser beam 311 may be determined by the signal 110 generated by the function generator 100.

The first pulse laser beam 311 may be generated from the laser light source 310, and the second pulse laser beam 313 may be extracted from the first pulse laser beam 311 by a beam splitter 314.

First, the behavior of the first pulse laser beam 311 is described below. The first pulse laser beam 311 may travel at a first pulse laser beam-pulse frequency f_311. The first pulse laser beam 311 may include a fourth-order harmonic laser beam. The first pulse laser beam-pulse frequency f_311 may be determined by the signal 110 generated by the function generator 100. The first pulse laser beam 311 may pass through the beam splitter 314 located on a path thereof and may be then be received by the electron beam generator 330. Here, the beam splitter 314 may include a color filter or mirror that adjusts the wavelength of the laser beam. When the first pulse laser beam 311 is emitted to the electron beam generator 330, the energy level exceeds the electron emission threshold energy by the first pulse laser beam 311. At the moment of exceeding the electron emission threshold energy, the electron beam generator 330 may generate an electron beam 331 having the same pulse frequency as the first pulse laser beam-pulse frequency f_311 of the first pulse laser beam 311. Therefore, the electron beam-pulse frequency f_331 may be the same as the first pulse laser beam-pulse frequency f_311. The behavior of the electron beam 331 is described after the behavior of the second pulse laser beam 313 is described.

Next, the behavior of the second pulse laser beam 313 is described. The second pulse laser beam 313 may be extracted from the first pulse laser beam 311 by the beam splitter 314. The second pulse laser beam 313 may travel at a second pulse laser beam-pulse frequency f_313. The second pulse laser beam 313 may include a second-order harmonic laser beam. The second pulse laser beam 313 may include a laser beam having time resolution. At least one mirror 316 may be located on the path of the second pulse laser beam 313 extracted by the beam splitter 314. The mirror 316 may change the path of the second pulse laser beam 313 by reflecting the second pulse laser beam 313 and also change the angle of incidence at which the second pulse laser beam 313 is incident onto the substrate W. The angle and number of mirrors 316 are not limited to the angle in number of mirrors in the drawings.

The beam splitter 314 includes a color filter or mirror that adjusts the wavelength of the laser beam, and thus, the wavelength of the first pulse laser beam 311 may be different from the wavelength of the second pulse laser beam 313. Also, the pulse frequency of the first pulse laser beam 311 may be equal to the pulse frequency of the second pulse laser beam 313. Therefore, the second pulse laser beam-pulse frequency f_313 may be equal to the first pulse laser beam-pulse frequency f_311. The traveling directions of the first pulse laser beam 311 and the second pulse laser beam 313 may be perpendicular to each other, but the embodiment is not limited thereto.

The incident angle of the second pulse laser beam 313 when emitted onto the substrate W may be different from the angle at which the electron beam 331 emitted from the electron beam generator 330 is incident onto the substrate W. The second pulse laser beam 313 may be emitted onto the substrate W without interfering with the electron beam 331, and these beams may not affect each other. The second pulse laser beam 313 may travel in a mode that pumps the substrate W, and the second pulse laser beam 313 may include a second-order harmonic wavelength and operate as a source of ultrasonic waves 210 by the photoacoustic effect on the upper portion of the substrate W.

Referring to FIG. 5, an ultrasonic signal, as a reflected signal, generated in the upper portion of the substrate W by the second pulse laser beam 313 may include information about the inner structure of the substrate W. Accordingly, the ultrasonic wave 210 generated by the second pulse laser beam 313 may be transmitted to the lower portion of the substrate W, reflected from the lower portion of the substrate W, and then transmitted to the upper portion of the substrate W. Therefore, a surface wave signal s_210 may be generated on the upper surface of the substrate W. The second pulse laser beam 313 may be used as a generator of a single ultrasonic wave 210 or may interfere with the ultrasonic signal generated from the ultrasonic generation module 200. Referring to FIGS. 3 to 6 together, when the ultrasonic generation module 200 operates and the second pulse laser beam 313 is emitted at the same time, an ultrasonic wave 213 (also referred to as a third ultrasonic wave) generated by the second pulse laser beam 313 may interfere with a first ultrasonic wave 211 generated by the ultrasonic generation module 200 and may be used to amplify or cancel only the desired signal.

Referring to FIG. 2B, the second pulse laser beam 313 may be omitted, and the ultrasonic generation module 200 may be used as the generator of the single ultrasonic wave 210. Therefore, the ultrasonic waves 210 according to an embodiment of the present discourse may include the ultrasonic waves generated by the ultrasonic generation module 200, the ultrasonic waves generated by the photoacoustic effect of the second pulse laser beam 313, or the ultrasonic waves generated by overlapping the ultrasonic waves generated by the photoacoustic effect of the second pulse laser beam 313 with the ultrasonic waves generated by the ultrasonic generation module 200.

Next, the behavior of the electron beam 331 is described below. The electron beam 331 may be emitted from the electron beam generator 330. The first pulse laser beam 311 may be emitted to the electron beam generator 330, and the electron beam generator 330 may emit the electron beam 331 at the moment an energy level exceeds the electron emission threshold energy by the first pulse laser beam 311. Accordingly, the electron beam generator 330 may generate the electron beam 331 having the same pulse width and period as the first pulse laser beam-pulse frequency f_311 having a fourth-order harmonic wavelength. According to embodiments of the present disclosure, the electron beam 331 may pass through an electron beam optical system. For example, a Schottky-type or thermal field emission-type electron beam generator may be used as the electron beam generator 330. The electron beam 331 may be emitted by applying an acceleration voltage to the electron beam generator 330. According to embodiments of the present disclosure, an anode may be used as an acceleration electrode, and the electron beam 331 may be accelerated by the voltage applied between the electron beam generator 330 and the anode. A magnetic lens may focus and accelerate the electron beam 331. The scanning coil may scan a specimen (e.g., the substrate W) one-dimensionally or two-dimensionally with the electron beam 331.

The electron beam 331 may be emitted onto the upper portion of the substrate W and scan the upper portion of the substrate W along an electron beam scan path w_331.

The electron beam 331 having a periodic electron beam-pulse frequency f_331 may be incident onto the upper portion of the substrate W. In general, an electron beam emitted to the substrate W may acquire an image by obtaining, as a signal, only information about the upper surface of the substrate W. On the other hand, the electron beam 331 according to an embodiment of the present disclosure may interfere with the surface wave signal s_210 generated by the ultrasonic wave 210 in the upper portion of the substrate W, and as a result, backscattered electrons (BSEs) 351 and/or secondary electrons (SEs) 371 may be generated. Therefore, an image may be acquired by obtaining not only information about the upper surface of the substrate W but also information about the inside of the substrate W. More specifically, the BSEs 351 and/or the SEs 371 may be detected by the backscattered electron (BSE) detector 350 and/or the secondary electron (SE) detector 370, respectively. The surface wave signal s_210 including the information about the inside of the substrate W may be transformed into an image by the detected and converted signal, using the ultrasonic waves 210 that are transmitted to the upper portion of the substrate W.

As used herein, the BSEs 351 may correspond to electrons, in the electron beam 331 emitted onto the substrate W, which are scattered by colliding with the substrate W. Also, the SEs 371 may correspond to electrons which are scattered when electrons placed on the substrate W are discharged by the electron beam 331 emitted onto the substrate W. The average value of energy retained by the BSEs 351 may be greater than the average value of energy retained by the SEs 371. The electron beam measurement module 300 of each of the semiconductor substrate inspection device 1000, the semiconductor substrate inspection device 1000a, and the semiconductor substrate inspection device 1000b may include the energy filter 353 located on one side of the BSE detector 350. The energy filter 353 may filter the SEs 371 that have relatively less energy than the BSEs 351. Accordingly, the energy filter 353 may filter the SEs 371 scattered toward the BSE detector 350 and may cancel or reduce signal noise caused by the BSEs 351.

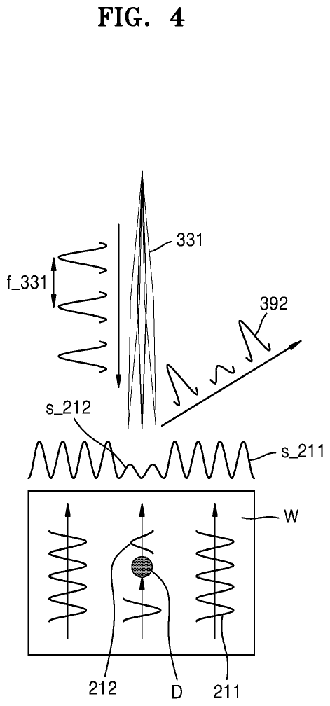

FIG. 3 is a conceptual diagram showing a state in which a substrate inspection is performed using an ultrasonic generation module on a defect-free substrate W, according to an embodiment. FIG. 4 is a conceptual diagram showing a state in which a substrate inspection is performed using the ultrasonic generation module on a defective substrate W, according to an embodiment.

Each of FIGS. 3 and 4 shows a state in which the ultrasonic generation module is used as a single ultrasonic generation source. Referring to FIG. 3 together with FIG. 2A, there is no defect in the substrate W, and the ultrasonic generation module 200 disposed below the substrate W may receive the signal 110 from the function generator 100 and generate at least one first ultrasonic wave 211. For example, a plurality of first ultrasonic waves 211 may be generated. The first ultrasonic waves 211, that are generated, may travel from the lower portion of the substrate W to the upper portion of the substrate W. The first ultrasonic waves 211 may be modulated differently by the ultrasonic generation module 200 depending on the thickness and/or material of the substrate W. The first ultrasonic waves 211 may generate a surface wave signal s_211 after interfering with the inside of the substrate W. As used herein, the surface wave signal s_211 may be interpreted as an ultrasonic near-field.

As described above, the surface wave signal s_211 may interfere with the electron beam 331 that is emitted from the electron beam generator 330. The electron beam 331 may generate a first electron signal 391 after interfering with the surface wave signal s_211. Here, the first electron signal 391 refers to a signal obtained by adding the pulse signal generated by the BSEs 351 and the signal generated by the SEs 371 in FIG. 2A. When the inside of the substrate W is homogeneous without defects, the first ultrasonic waves 211 are not interfered with by a defect, and thus, the surface wave signal s_211 may be formed uniformly.

Referring to FIG. 4 together with FIG. 2A, there is a defect D inside the substrate W, and the ultrasonic generation module 200 disposed below the substrate W may receive the signal 110 from the function generator 100 and generate at least one first ultrasonic wave 211. For example, a plurality of first ultrasonic waves 211 may be generated. The first ultrasonic waves 211 that are generated may travel from the lower portion of the substrate W to the upper portion of the substrate W. At least one first ultrasonic wave 211 among the plurality of first ultrasonic waves 211 may interfere with the defect D formed inside the substrate W and be converted into a second ultrasonic wave 212. The second ultrasonic wave 212 may have different amplitude and/or phase from the first ultrasonic wave 211. The first ultrasonic waves 211 may pass through and travel from the lower portion of the substrate W to the upper portion of the substrate W and the second ultrasonic wave 212 may pass through and travel from the conversion point to the upper portion of the substrate W. However, the traveling path of each of the ultrasonic waves may change depending on the location of the defect D. The first ultrasonic wave 211 and the second ultrasonic wave 212 may generate a surface wave signal s_211 and a surface wave interference signal s_212 after interfering with the inside of the substrate W. The surface wave signal s_211 generated by the first ultrasonic wave 211 that has interfered only with the substrate W without interference with the defect D may have amplitudes and/or phases different from amplitudes and/or phases of the surface wave interference signal s_212 generated by the second ultrasonic wave 212 that has interfered with the defect D. Therefore, the information, by which the internal state of the substrate W or the defect D existing inside the substrate W is identified, may be obtained by combining the surface wave signal s_211 and the surface wave interference signal s_212.

The surface wave signal s_211 and the surface wave interference signal s_212 may interfere with the electron beam 331 emitted from the electron beam generator 330, as described above. The electron beam 331 may generate a second electron signal 392 after interfering with the surface wave signal s_211 and the surface wave interference signal s_212. Here, the second electron signal 392 refers to a signal obtained by adding the pulse signal generated by the BSEs 351 and the signal generated by the SEs 371 in FIG. 2A. When the substrate W is not homogeneous due to the defect D existing inside the substrate W, the surface wave signal s_211 and the surface wave interference signal s_212 may be formed, and thus, the second electron signal 392 may also be formed non-uniformly.

FIG. 5 is a conceptual diagram showing a state in which a substrate inspection is performed using a pulse laser beam on a defect-free substrate W, according to an embodiment. FIG. 6 is a conceptual diagram showing a state in which a substrate inspection is performed using the pulse laser beam on a defective substrate W, according to an embodiment.

Each of FIGS. 5 and 6 shows a state in which the second pulse laser beam 313 is used as a single ultrasonic generation source. As described above, when the second pulse laser beam 313 reaches the upper surface of the substrate W, a third ultrasonic wave 213 may be generated by the photoacoustic effect. The third ultrasonic wave 213 may include a reflected signal that is generated on the upper surface of the substrate W, travels to the lower portion of the substrate W, is reflected from the lower portion of the substrate W, and then reaches the upper surface of the substrate W again.

Referring to FIG. 5 together with FIG. 2A, there is no defect in the substrate W, and the second pulse laser beam 313 may be emitted to the upper portion of the substrate W to generate at least one third ultrasonic wave 213. Accordingly, a plurality of third ultrasonic waves 213 may be formed, and the embodiment is not limited to the drawings. The third ultrasonic waves 213 may be generated differently by the second pulse laser beam 313 depending on the thickness and/or material of the substrate W. The third ultrasonic waves 213 may generate a surface wave signal s_213 after interfering with the inside of the substrate W. As used herein, the surface wave signal s_213 may be interpreted as an ultrasonic near-field. The surface wave signal s_213 in FIG. 5 may be different from the surface wave signal s_211 in FIG. 3.

As described above, the surface wave signal s_213 may interfere with the electron beam 331 that is emitted from the electron beam generator 330. The electron beam 331 may generate a third electron signal 393 after interfering with the surface wave signal s_213. When the inside of the substrate W is homogeneous without defects, the transmitted third ultrasonic waves 213 are not interfered with by a defect, and thus, the surface wave signal s_213 may be formed uniformly. The third electron signal 393 in FIG. 5 may be different from the first electron signal 391 in FIG. 3.

Referring to FIG. 6 together with FIG. 2A, there is a defect D in the substrate W, and the second pulse laser beam 313 may be emitted to the upper portion of the substrate W to generate at least one third ultrasonic wave 213. Accordingly, a plurality of third ultrasonic waves 213 may be formed, and the embodiment is not limited to the drawings. The third ultrasonic waves 213 may be generated differently by the second pulse laser beam 313 depending on the thickness and/or material of the substrate W. The third ultrasonic waves 213 may generate a surface wave signal s_213 after interfering with the inside of the substrate W. At least one third ultrasonic wave 213 among the plurality of third ultrasonic waves 213 may interfere with the defect D formed inside the substrate W and be converted into a fourth ultrasonic wave 214. The fourth ultrasonic wave 214 may have a different amplitude and/or phase from an amplitude and/or phase of the third ultrasonic wave 213. Also, the fourth ultrasonic wave 214 may have a different amplitude and/or phase from an amplitude and/or phase of the second ultrasonic wave 212 shown in FIG. 4. The third ultrasonic waves 213 may travel from the upper portion of the substrate W to the lower portion of the substrate W, be reflected from the lower portion of the substrate W, and travel to the upper portion of the substrate W. The fourth ultrasonic wave 214 may travel from the conversion point to the upper portion of the substrate W. However, the traveling path of each of the ultrasonic waves may change depending on the location of the defect D. The third ultrasonic wave 213 and the fourth ultrasonic wave 214 may generate a surface wave signal s_213 and a surface wave interference signal s_214 after interfering with the inside of the substrate W. The surface wave signal s_213 and the surface wave interference signal s_214 of FIG. 6 may be different from the surface wave signal s_211 and the surface wave interference signal s_212 of FIG. 4. The surface wave signal s_213 generated by the third ultrasonic wave 213, that has interfered only with the substrate W without interference with the defect D, may have amplitudes and/or phases different from amplitudes and/or phases of the surface wave interference signal s_214 generated by the fourth ultrasonic wave 214 that has interfered with the defect D. Therefore, the information, by which the internal state of the substrate W or the defect D existing inside the substrate W is identified, may be obtained by combining the surface wave signal s_213 and the surface wave interference signal s_214.

The surface wave signal s_213 and the surface wave interference signal s_214 may interfere with the electron beam 331 emitted from the electron beam generator 330. The electron beam 331 may generate a fourth electron signal 394 after interfering with the surface wave signal s_213 and the surface wave interference signal s_214. Here, the fourth electron signal 394 refers to a signal obtained by adding the pulse signal generated by the BSEs 351 and the signal generated by the SEs 371 in FIG. 2A. When the substrate W is not homogeneous due to the defect D existing inside the substrate W, the surface wave signal s_213 and the surface wave interference signal s_214 may be formed, and thus, the fourth electron signal 394 may also be formed non-uniformly.

According to embodiments of the present disclosure, the semiconductor substrate inspection device may further include a controller and a processor in order to measure the first electron signal 391, the second electron signal 392, the third electron signal 393, and the fourth electron signal 394 and process the information. The controller may be configured to control the operations of the function generator 100, the laser light source 310, the ultrasonic generation module 200, and the electron beam generator 330. The controller may be configured to generate signals for controlling oscillation of the laser light source 310, behavior of each of the function generator 100 and the ultrasonic generation module 200, and turning on/off of the BSE detector 350 and the SE detector 370.

The processor may be configured to process electric signals obtained by the BSE detector 350 and the SE detector 370. The processor may, for example, preprocess measurement data including electric signals obtained by the BSE detector 350 and the SE detector 370 and measure information about the inside of the substrate W on the basis of the intensity, period, and/or frequency of the first and/or second pulse laser beam.

According to embodiments, each of the controller and the processor may be provided as hardware, firmware, software, or any combination thereof. For example, the controller and the processor may include a computing devices, such as a workstation computer, a desktop computer, a laptop computer, and a tablet computer. The controller and the processor may include a simple controller, complex processors, such as a microprocessor, a central processing unit (CPU), and a graphics processing unit (GPU), a processor configured by software, dedicated hardware, or firmware. The controller and the processor may be configured by, for example, a general-purpose computer, or application-specific hardware, such as a digital signal processor (DSP), a field programmable gate array (FPGA), and an application specific integrated circuit (ASIC).

According to some embodiments, the operations of the controller and the processor may be performed by commands stored on a machine-readable medium that may be read and executed by one or more processors. Here, the machine-readable medium may include any mechanism for storing and/or transmitting information in a form readable by a machine (e.g., a computing device). For example, the machine-readable media may include read only memory (ROM), random access memory (RAM), magnetic disk storage media, optical storage media, flash memory devices, electrical, optical, acoustic, or other forms of radio signals (e.g., carrier waves, infrared signals, digital signals, etc.), and any other signals.

Also, firmware, software, routines, and instructions may be configured to perform the operations described for the controller and the processor or any process described below. However, this is for convenience of description, and the operations of the controller and the processor may be performed by a computing device, a processor, another device executing firmware, software, routines, and instructions, etc.

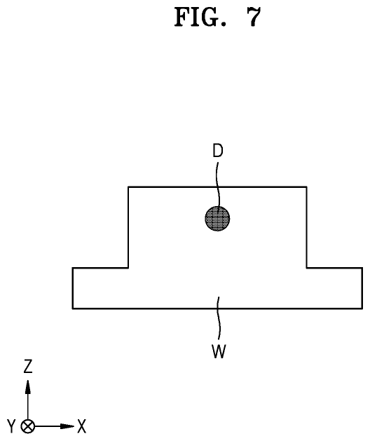

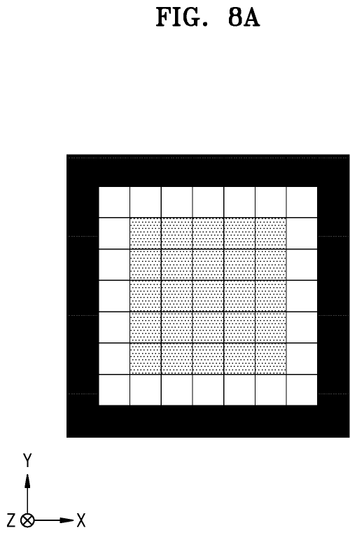

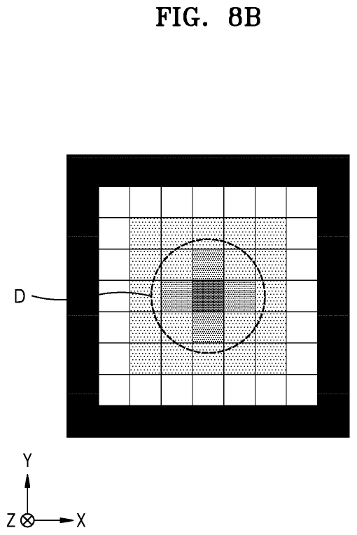

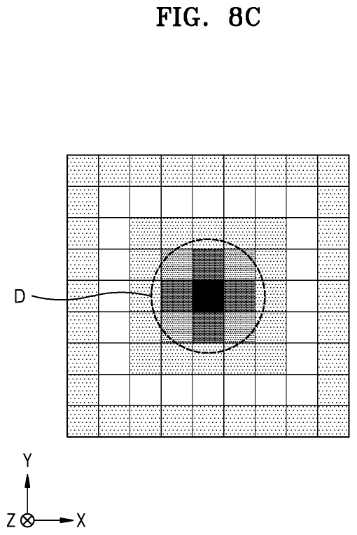

FIG. 7 is a cross-sectional view showing a substrate W according to an embodiment. FIGS. 8A to 8C are images derived by inspection of the substrate W, according to an embodiment. The ultrasonic waves described with reference to FIGS. 7 to 10D may include the ultrasonic waves generated by the ultrasonic generation module, the ultrasonic waves generated by the photoacoustic effect of the second pulse laser beam, or the ultrasonic waves generated by overlapping the ultrasonic waves generated by the photoacoustic effect of the second pulse laser beam with the ultrasonic waves generated by the ultrasonic generation module.

Referring to FIG. 7, a defect D exists inside the substrate W, and levels at both ends of the substrate W are lower than a level at the center of the substrate W.

Referring to FIG. 8A together with FIG. 7, FIG. 8A shows an image obtained by measuring only scattered secondary electrons (SEs) in the electron beam generated from the electron beam generator, in a state in which the ultrasonic generation module is not turned on for the substrate W. Since there is no ultrasonic wave passing through the substrate W, information about the inside of the substrate W is not displayed. As a result, although there is a defect D inside the substrate W, only a level difference in the surface shape of the substrate W may be displayed in the image of FIG. 8A.

Referring to FIG. 8B together with FIG. 7, FIG. 8B shows an image obtained by measuring only scattered SEs in the electron beam generated from the electron beam generator, in a state in which the ultrasonic generation module is turned on for the substrate W. Here, the ultrasonic wave generated by the ultrasonic generation module includes a single ultrasonic wave. There is an ultrasonic wave that passes through the substrate W, and accordingly, information inside the substrate W may be displayed. As a result, the ultrasonic wave is interfered with by a defect D present inside the substrate W, and a dark surface shape due to the interference may be measured in the center of the image. More specifically, the dark edge of the outermost portion of the image corresponds to a signal according to the surface shape of the substrate W, and the shape of the dark central portion of the image corresponds to a signal according to the defect D inside the substrate W.

Referring to FIG. 8C together with FIG. 7, FIG. 8C shows an image obtained by comprehensively measuring electrons (e.g., by measuring not only the scattered secondary electrons (SEs) but also backscattered electrons (BSEs) in the electron beam generated from the electron beam generator) in a state in which the ultrasonic generation module is turned on for the substrate W. Here, the ultrasonic wave generated by the ultrasonic generation module includes an ultrasonic wave that is modulated into a specific waveform according to the characteristics of the substrate W. Also, the BSEs are also scattered from the electron beam that is modulated by the function generator. There is an ultrasonic wave that passes through the substrate W, and accordingly, information inside the substrate W may be displayed. Also, the ultrasonic generation module and the electron beam measurement module including the BSE detector adjust the waveform by the function generator so as to minimize interference with the inner structure of the substrate W. Accordingly, the outermost dark edge signal due to the surface shape may be reduced, and the dark central signal due to the internal defect may be highlighted and measured.

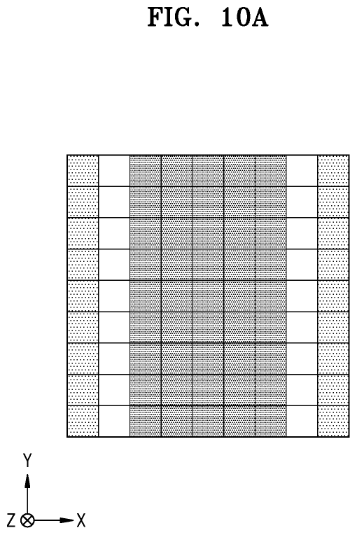

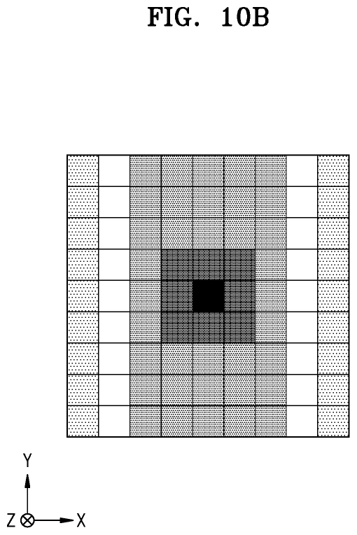

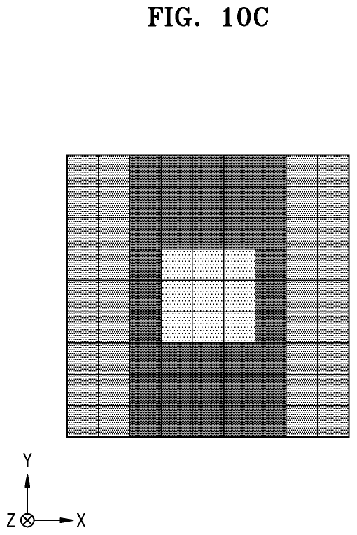

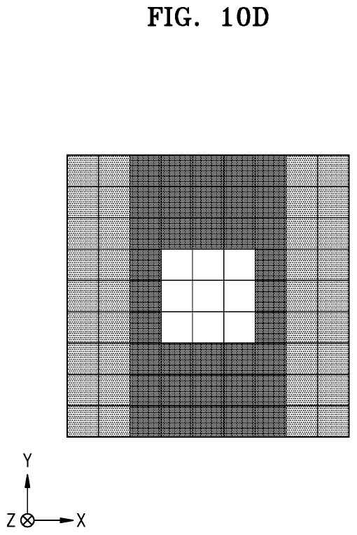

FIG. 9 is a cross-sectional view showing a substrate W according to an embodiment. FIGS. 10A to 10D are images derived by inspection of the substrate W, according to an embodiment.

Referring to FIG. 9, substrates W include a plurality of layers, and the surface shapes of the substrates W respectively forming layers are different from each other.

Referring to FIG. 10A together with FIG. 9, FIG. 10A shows an image obtained by measuring only scattered SEs in the electron beam generated from the electron beam generator, in a state in which the ultrasonic generation module is not turned on for the substrate W. Since there is no ultrasonic wave passing through the substrate W, the information about the inside of the substrate W is not displayed. As a result, only the surface shape of an upper substrate W may be shown in the image, and the surface shape of a lower substrate W may not be shown in the image.

Referring to FIG. 10B together with FIG. 9, FIG. 10B shows an image obtained by measuring only scattered SEs in the electron beam generated from the electron beam generator, in a state in which the ultrasonic generation module is turned on for the substrate W. Here, the ultrasonic wave generated by the ultrasonic generation module includes a single ultrasonic wave. There is an ultrasonic wave that passes through the substrate W, and accordingly, information inside the substrate W may be displayed. As a result, the image may show not only the surface shape of the upper substrate W but also the surface shape of the lower substrate W. More specifically, the vertical line on the outer edge of the image corresponds to a signal according to the surface shape of the upper substrate W, and the shape of the dark central portion of the image corresponds to a signal according to the surface shape of the lower substrate W.

Referring to FIG. 10C together with FIG. 9, FIG. 10C shows an image obtained by comprehensively measuring electrons (e.g., by measuring not only the scattered SEs but also BSEs in the electron beam generated from the electron beam generator) in a state in which the ultrasonic generation module is not turned on for the substrate W. The BSEs are scattered from the electron beam that is modulated by the function generator. Since there is no ultrasonic wave passing through the substrate W, information about the inside of the substrate W is not displayed. However, the BSEs have higher energy than the SEs and may thus reach relatively deeper places. As a result, not only the image of the surface shape of the upper substrate W but also the image of the surface shape of the lower substrate W may be expressed. However, even in this case, the electron beam measurement module including the BSE detector adjusts the waveform by the function generator so as to minimize interference with the inner structure of the substrate W. Accordingly, a signal due to the surface shape of the upper substrate W may be reduced, and a signal due to the surface shape of the lower substrate W may be highlighted.

Referring to FIG. 10D together with FIG. 9, FIG. 10D shows an image obtained by comprehensively measuring electrons (e.g., by measuring not only the SEs but also BSEs in the electron beam generated from the electron beam generator) in a state in which the ultrasonic generation module is turned on for the substrate W. Here, the ultrasonic wave generated by the ultrasonic generation module includes an ultrasonic wave that is modulated into a specific waveform according to the characteristics of the substrate W. Also, the BSEs are also scattered from the electron beam that is modulated by the function generator. There is an ultrasonic wave that passes through the substrate W. Also, the BSEs have higher energy than the SEs and may thus reach relatively deeper places. As a result, not only the image of the surface shape of the upper substrate W but also the image of the surface shape of the lower substrate W may be expressed. However, the ultrasonic generation module and the electron beam measurement module including the BSE detector adjust the waveform by the function generator so as to minimize interference with the inner structure of the substrate W. Accordingly, a signal due to the surface shape of the upper substrate W may be reduced, and a signal due to the surface shape of the lower substrate W may be highlighted. Accordingly, the central portion of FIG. 10D showing the surface shape of the lower substrate W may be clearly distinguished from other regions than the central portion of FIG. 10C.

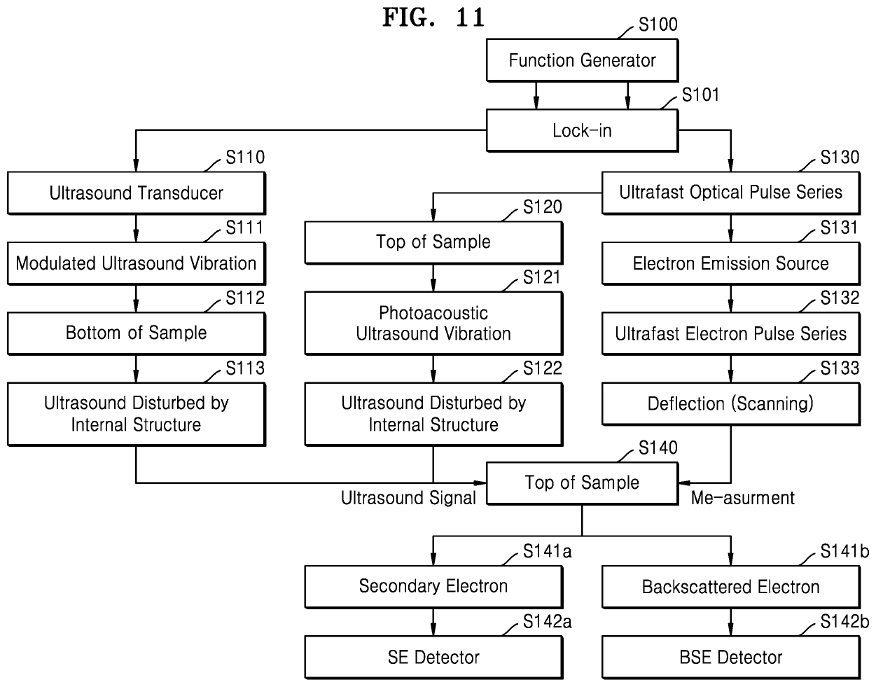

FIG. 11 is a flowchart of a semiconductor substrate inspection according to an embodiment.

Referring to FIG. 11, a series of operations may be performed to inspect loading and alignment of a substrate, alignment of a beam or stage, or the like.

Here, an ultrasound transducer may be the ultrasonic generation module 200 of FIG. 2A, an ultrafast electron beam measurement module may be the electron beam measurement module 300 of FIG. 2A, and a laser pulse generator may be the laser light source 310 of FIG. 2A. A sample may be the substrate W of FIG. 2A. Fourth-order harmonic pulse laser may be the first pulse laser beam 311 of FIG. 2A. Second-order harmonic pulse laser may be the second pulse laser beam 313 of FIG. 2A. Hereinafter, repeated descriptions of the same terms may be omitted.

When a substrate is loaded on a stage for inspection, a function for measurement may be generated in a function generator (operation S100). The function generator may lock in a signal (operation S101). A function signal may be transmitted to the ultrasound transducer of an ultrasonic near-field generation module (operation S110). Also, the function signal may be transmitted to a laser pulse generator of the ultrafast electron beam measurement module (operation S130).

The ultrasonic transducer may generate ultrasonic vibration of which a waveform is adjusted to be optimized for the substrate (operation S111), and an ultrasonic wave may be transmitted to the lower portion of the sample (operation S112). The ultrasonic vibration transmitted to the lower portion of the sample may be interfered with by the internal structure of the sample and transmitted to the upper portion of the sample as an ultrasonic signal (operation S113).

In the laser pulse generator, the second-order harmonic pulse laser in periodic laser pulses may be extracted from the fourth-order harmonic pulse laser by a beam splitter having wavelength selectivity, and the second-order harmonic pulse laser may be emitted to the upper portion of the sample (operation S120). The emitted second-order harmonic pulse laser may produce ultrasonic vibrations at the upper portion of the sample by the photoacoustic effect (operation S121). The ultrasonic vibration may be interfered with by the internal structure of the sample (operation S122) and transmitted back to the upper portion of the sample (operation S140), or the ultrasonic vibration may be interfered with by ultrasonic signals generated by the ultrasonic transducer (operation S122).

The fourth-order harmonic pulse laser in the periodic laser pulses generated from the laser pulse generator may pass through the beam splitter having wavelength selectivity and may be then received by the electron beam generator (operation S131). The electron beam generator may exceed electron emission threshold energy by the fourth-order harmonic pulse laser and generate an electron beam having the same pulse width and period as the fourth-order harmonic pulse laser (operation S132). The generated electron beam may pass through the electron beam optical system, be incident on the upper portion of the sample, and scan the sample (operation S133).

After the electron beam is emitted to the upper portion of the sample (operation S140), generating of SEs (operation S141a) and generating of BSEs (operation S141b) at the upper portion of the sample may be performed in parallel. The amount of generated electrons and the properties of signals may be changed by the surface wave vibration at the upper portion of the sample. The SEs may reach the SE detector and be converted into electrical signals (operation S142a). The BSEs may reach the BSE detector and be converted into electrical signals (operation S142b). The electrical signals may be combined and converted into a two-dimensional image according to scan positions.

While non-limiting example embodiments have been particularly shown and described, it will be understood that various changes in form and details may be made therein without departing from the spirit and scope of the present disclosure.

What is claimed is:

1. A semiconductor substrate inspection device comprising:
a function generator configured to generate a first signal and a second signal;
an ultrasonic generator configured to receive the first signal generated from the function generator, generate an ultrasonic wave based on the first signal, and generate a surface wave signal on an upper surface of a substrate using the ultrasonic wave; and
an electron beam measurer configured to inspect the surface wave signal,
wherein the electron beam measurer comprises:
a laser light source configured to receive the second signal generated from the function generator and generate a first pulse laser beam based on the second signal;
an electron beam generator configured to receive the first pulse laser beam and generate an electron beam that is emitted onto the upper surface of the substrate; and
a backscattered electron detector configured to detect backscattered electrons generated based on the electron beam being incident on the substrate.

2. The semiconductor substrate inspection device of claim 1, wherein the electron beam measurer further comprises:
a beam splitter configured to extract a second pulse laser beam from the first pulse laser beam; and
a mirror located on a path of the second pulse laser beam, the mirror configured to cause the second pulse laser beam to be incident on the upper surface of the substrate.

3. The semiconductor substrate inspection device of claim 2, wherein the second pulse laser beam is incident on the substrate along an axis different from an axis along which the electron beam is incident on the substrate.

4. The semiconductor substrate inspection device of claim 2, wherein the beam splitter comprises a color filter that is configured to adjust a wavelength of the first pulse laser beam or the second pulse laser beam, and
wherein the first pulse laser beam and the second pulse laser beam have wavelengths different from each other.

5. The semiconductor substrate inspection device of claim 2, wherein the first pulse laser beam and the second pulse laser beam have a same pulse frequency.

6. The semiconductor substrate inspection device of claim 1, wherein the electron beam measurer further comprises a secondary electron detector configured to detect secondary electrons generated from the substrate.

7. The semiconductor substrate inspection device of claim 6, wherein the electron beam measurer further comprises an energy filter located on one side of the backscattered electron detector, and
wherein the energy filter is configured to filter the secondary electrons and cancel or reduce signal noise caused by the backscattered electrons.

8. The semiconductor substrate inspection device of claim 1, wherein the first signal and the second signal generated from the function generator comprise a lock-in signal, and
wherein the lock-in signal synchronizes the first pulse laser beam and the ultrasonic wave with each other.

9. The semiconductor substrate inspection device of claim 1, wherein the function generator is configured to individually modulate an amplitude and a pulse frequency of the first signal that is input to the ultrasonic generator and an amplitude and a pulse frequency of the second signal that is input to the laser light source.

10. The semiconductor substrate inspection device of claim 1, wherein the ultrasonic generator is on a lower surface of the substrate,
wherein frequency of the ultrasonic wave generated from the ultrasonic generator is 10 kHz to 10 MHz, and
wherein the ultrasonic wave is transmitted from a lower portion of the substrate to an upper portion of the substrate.

11. The semiconductor substrate inspection device of claim 2, wherein the second pulse laser beam is emitted onto the upper surface of the substrate and generates an ultrasonic wave by a photoacoustic effect, and
wherein the ultrasonic wave generated by the second pulse laser beam is transmitted to a lower portion of the substrate, reflected from the lower portion of the substrate, and transmitted to an upper portion of the substrate, thereby generating a surface wave signal on the upper surface of the substrate.

12. The semiconductor substrate inspection device of claim 2, wherein the ultrasonic wave generated by the second pulse laser beam interferes with the ultrasonic wave generated by the ultrasonic generator and is thus amplified or cancelled.

13. The semiconductor substrate inspection device of claim 1, wherein a period of the electron beam generated by the electron beam generator is based on a pulse frequency of the first pulse laser beam, and
wherein the period of the electron beam is less than or equal to 1 picosecond (ps).

14. A semiconductor substrate inspection device comprising:
an ultrasonic generator configured to generate an ultrasonic wave that is modulated, wherein the ultrasonic wave generates a surface wave signal on an upper surface of a substrate;
an electron beam generator configured to scan the upper surface of the substrate and generate an electron beam that is scattered by interference with the surface wave signal;
a backscattered electron detector configured to detect backscattered electrons that are generated based on the electron beam being incident on the substrate;
a secondary electron detector configured to detect secondary electrons generated from the substrate;
a laser light source configured to generate a first pulse laser beam, wherein a period of the electron beam, generated by the electron beam generator, is based on a pulse frequency of the first pulse laser beam;
a beam splitter configured to extract a second pulse laser beam from the first pulse laser beam;
a mirror on a path of the second pulse laser beam, the mirror configured to cause the second pulse laser beam to be incident on the upper surface of the substrate; and
a function generator configured to generate a first function signal and a second function signal, and transmit the first function signal and the second function signal to the ultrasonic generator and the laser light source, respectively.

15. The semiconductor substrate inspection device of claim 14, wherein the second pulse laser beam is incident on the substrate along an axis different from an axis along which the electron beam is incident on the substrate.

16. The semiconductor substrate inspection device of claim 14, wherein the beam splitter comprises a color filter that is configured to adjust a wavelength of the first pulse laser beam or the second pulse laser beam,
wherein the first pulse laser beam and the second pulse laser beam have wavelengths different from each other, and
wherein the first pulse laser beam and the second pulse laser beam have a same pulse frequency.

17. The semiconductor substrate inspection device of claim 14, further comprising an energy filter located on one side of the backscattered electron detector,
wherein the energy filter is configured to filter the secondary electrons and cancel or reduce signal noise caused by the backscattered electrons.

18. The semiconductor substrate inspection device of claim 14, wherein the first function signal and the second function signal generated from the function generator comprises a lock-in signal, and
wherein the function generator is configured to individually modulate an amplitude and a pulse frequency of the first function signal that is input to the ultrasonic generator and an amplitude and a pulse frequency of the second function signal that is input to the laser light source.

19. The semiconductor substrate inspection device of claim 14, wherein the ultrasonic generator is on a lower surface of the substrate,
wherein the ultrasonic wave generated from the ultrasonic generator has a frequency of 10 kHz to 10 MHz and is transmitted from a lower portion of the substrate to an upper portion of the substrate,
wherein the second pulse laser beam is emitted onto the upper surface of the substrate and generates an ultrasonic wave by a photoacoustic effect,
wherein the ultrasonic wave generated by the second pulse laser beam is transmitted to the lower portion of the substrate, reflected from the lower portion of the substrate, and transmitted to the upper portion of the substrate, and
the ultrasonic wave generated by the second pulse laser beam interferes with the ultrasonic wave generated by the ultrasonic generator and is thus amplified or cancelled.

20. A semiconductor substrate inspection device comprising:
an ultrasonic generator configured to generate a first ultrasonic wave that is modulated, wherein the first ultrasonic wave generates a surface wave signal on an upper surface of a substrate;
an electron beam generator configured to scan the upper surface of the substrate and generate an electron beam that is scattered by interference with the surface wave signal;
a backscattered electron detector configured to detect backscattered electrons that are generated based on the electron beam being incident on the substrate;
a secondary electron detector configured to detect secondary electrons generated from the substrate;
an energy filter on one side of the backscattered electron detector and configured to filter the secondary electrons to cancel or reduce signal noise caused by the backscattered electrons;
a laser light source configured to generate a first pulse laser beam, wherein a period of the electron beam, generated by the electron beam generator, is based on a pulse frequency of the first pulse laser beam;
a beam splitter configured to extract a second pulse laser beam from the first pulse laser beam;
a mirror on a path of the second pulse laser beam, the mirror configured to cause the second pulse laser beam to be incident on the upper surface of the substrate; and
a function generator configured to generate a first function signal and a second function signal, and transmit the first function signal and the second function signal to the ultrasonic generator and the laser light source, respectively,
wherein the second pulse laser beam is emitted onto the upper surface of the substrate and generates a second ultrasonic wave by a photoacoustic effect,
wherein the second pulse laser beam is incident on the substrate along an axis different from an axis along which the electron beam is incident on the substrate,
wherein the beam splitter comprises a color filter that is configured to adjust a wavelength of the first pulse laser beam or the second pulse laser beam,
wherein the first pulse laser beam and the second pulse laser beam have wavelengths different from each other,
wherein the first pulse laser beam and the second pulse laser beam have a same pulse frequency,
wherein the ultrasonic generator is on a lower surface of the substrate,
wherein the first ultrasonic wave generated from the ultrasonic generator has a frequency of 10 kHz to 10 MHz and is transmitted from a lower portion of the substrate to an upper portion of the substrate,
wherein the second ultrasonic wave generated by the second pulse laser beam is transmitted to the lower portion of the substrate, reflected from the lower portion of the substrate, and transmitted to the upper portion of the substrate,
wherein the second ultrasonic wave generated by the second pulse laser beam interferes with the first ultrasonic wave generated by the ultrasonic generator and is thus amplified or cancelled, and
wherein the surface wave signal generated by the ultrasonic generator interferes with the electron beam and is sensed by the backscattered electron detector and the secondary electron detector.
